(19) United States
(12) Patent Application Publication
(10) Pub. No.: US 2007/0132016 A1
(43) Pub. Date: Jun. 14, 2007

(54) TRENCH LD STRUCTURE

(76) Inventor: Matthew P. Elwin, West Glamorgan (GB)

Correspondence Address: OSTROLENK FABER GERB & SOFFEN, 1180 AVENUE OF THE AMERICAS, NEW YORK, NY, 100368403, US

(21) Appl. No.: 11/609,534

(22) Filed: Dec. 12, 2006

Related U.S. Application Data
(60) Provisional application No. 60/749,396, filed on Dec. 12, 2005.

(51) Int. Cl. H01L 29/94

(52) U.S. Cl. 257/330; 257/E29.201

(57) ABSTRACT

A lateral conduction MOSFET has a trench between and separating surface source and drain electrodes. A gate insulation lines one vertical wall of the trench and a polysilicon gate mass is disposed adjacent the gate insulator and fills a portion of the width of the trench. The conduction path from surface source to surface drain is thus elongated by the periphery of the depth of the trench without using excessive surface area for the MOSFET die.

### RELATED APPLICATIONS

This application claims the benefit of U.S. Provisional Application No. 60/749,396, filed Dec. 12, 2005, the entire disclosure of which is incorporated by reference herein.

### FIELD OF THE INVENTION

This invention relates to trench type MOSFET devices and more specifically relates to a lateral conduction MOSFET with reduced gate to drain capacitance and reduced silicon area.

### BACKGROUND OF THE INVENTION

Lateral conduction MOSFETs are well known in which the source and drain electrodes are on the same die surface and are separated by a MOSgated inversion region. Such devices require a given silicon area because of the need for the lateral spacing of the source and drain areas. Such devices also have a relatively high gate-to-drain capacitance and thus a relatively high gate to drain charge Q_{GD}.

### BRIEF DESCRIPTION OF THE INVENTION

A lateral conduction device with drain and source electrodes on the same die surface is formed with trench gate structure, thus reducing the silicon area needed for a given cell and the Q_{GD} is reduced. More specifically, there is provided a lateral trench structure in which one side of the trench is filled with an insulation such as oxide, and the opposite side is filled with a gate oxide covered by a polysilicon gate. Source and drain diffusions are on opposite sides of the trench. The lateral conduction path then follows the outer periphery of the trench to produce a long path, using a small silicon surface area and a reduced gate/drain capacitance.

### BRIEF DESCRIPTION OF THE DRAWING

FIG. 1 shows a cross-section of an embodiment of the invention for a single “cell” of multi cell device.

### DETAILED DESCRIPTION OF THE DRAWING

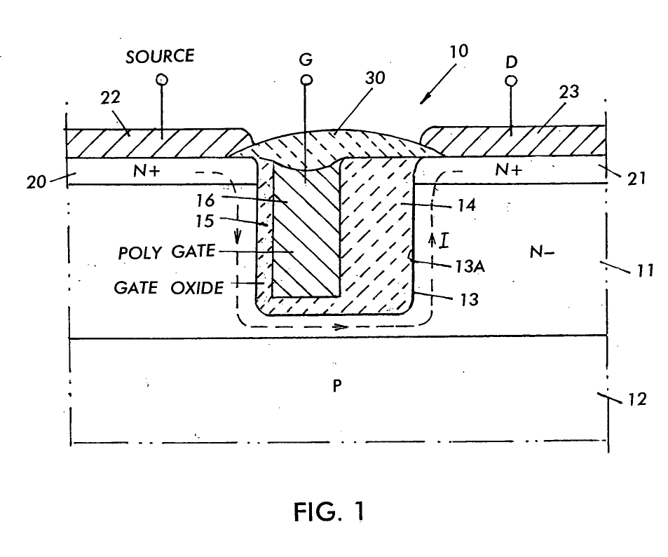

Referring to FIG. 1, there is shown a silicon die 10 which has an N⁻ epitaxial layer 11 on a P type substrate 12. The invention can also be employed with other semiconductor materials, for example, GaN. Further the concentration types for the device can be reversed.

A plurality of paralleled trenches or other openings 13 are formed in region 11 and about one half of the trench is filed with a dielectric, such as a silicon dioxide mass 14. The other side of trench 13 is lined with a thin oxide coating 15 (which may have a thickness less than 1000 Å) and a conductive polysilicon gate 16 fills about one half of the open trench. By way of example, the width of gate 16 may be about ½ the width of trench 13. In particular, the left hand side of polysilicon mass 16 which may be rectangular in cross-section, contacts the gate oxide 15 and is spaced from the opposite wall 13a of trench 13 by a large multiple of the thickness of oxide 15.

Source and drain diffusions 20 and 21 respectively are formed on opposite sides of trench 13 and are relatively closely spaced (by the width of trench 13) as compared to their spacing in a conventional lateral device.

Source and drain electrodes 22 and 23 are provided as shown, insulated from one another and from gate 16 by oxide cap 30.

Note that a plurality of identical die may be formed simultaneously in a common wafer using conventional fabrication techniques, with the separate die being singulated from the wafer after processing is completed.

An extended conduction path I for source/drain current is provided as shown in the dotted line current path which has a length defined in major part by the trench depth. Thus die surface area is saved for each cell. Further, the structure will have a reduced Q_{GD} as compared to the conventional lateral device.

Although the present invention has been described in relation to particular embodiments thereof, many other variations and modifications and other uses will become apparent to those skilled in the art. It is preferred, therefore, that the present invention be limited not by the specific disclosure herein.

What is claimed is:

1. A lateral conduction MOSFET comprising a semiconductor die having a body of one of the conductivity types and having first impurity concentration and having an upper surface layer of said one of the concentration types and having a higher concentration than said first concentration; a plurality of parallel spaced trenches formed in said die and extending from the top of said upper surface and through said upper layer and into said body of said die and separating said upper surface layer into a source region on one side of said trench and a drain region on the other side of said trench; a thin gate oxide lining at least one side wall of said trench and a conductive gate electrode having a given width filling a portion of said trench and in contact with the surface of said thin gate oxide and being spaced from the opposite wall of said trench by a large multiple of the thickness of said gate oxide; and source and drain electrodes connected to said source region and drain region respectively.

2. The device of claim 1, wherein said semiconductor die is monocrystalline silicon.

3. The device of claim 1, wherein said body and said upper surface layer have the N conductivity type.

4. The device of claim 1, wherein said conductive gate electrode is polysilicon.

5. The device of claim 1, wherein said conductive gate is rectangular in cross-section.

6. The device of claim 1, wherein the space between said gate electrode and said opposite wall is filled with an insulation material.

7. The device of claim 6, wherein said insulation material is an oxide.

8. The device of claim 7, wherein said semiconductor die is monocrystalline silicon.

9. The device of claim 7, wherein said conductive gate electrode is polysilicon.

10. The device of claim 9, wherein said conductive gate is rectangular in cross-section.
